(19) United States
(12) Patent Application Publication
(10) Pub. No.: US 2018/0061684 A1
(43) Pub. Date: Mar. 1, 2018

(54) OPTICAL HEATING OF LIGHT ABSORBING OBJECTS IN SUBSTRATE SUPPORT

(71) Applicant: Applied Materials, Inc., Santa Clara, CA (US)

(72) Inventor: Vijay D. Parkhe, San Jose, CA (US)

(21) Appl. No.: 15/685,911

(22) Filed: Aug. 24, 2017

Related U.S. Application Data
(60) Provisional application No. 62/380,295, filed on Aug. 26, 2016.

(51) Int. Cl. H01L 21/67; H01L 21/683; H01L 21/687

(52) U.S. Cl. CPC H01L 21/67115; H01L 21/6833; H01L 21/67011; H01L 21/68714; H01L 21/67248

(57) ABSTRACT

A substrate support assembly includes a ceramic plate and a cooling base coupled to the ceramic plate. A light absorbing object is disposed in the ceramic plate and a light transmission media is disposed in the cooling base. The light carrying medium is to direct light onto the light absorbing object to heat the light absorbing object.

### RELATED APPLICATIONS

This patent application claims the benefit under 35 U.S.C. §119(e) of U.S. Provisional Application No. 62/380,295, filed Aug. 26, 2016, incorporated herein in its entirety.

### TECHNICAL FIELD

Embodiments of the present invention relate to an apparatus for controlling substrate temperature using optical heating.

### BACKGROUND

Conventional electronic device manufacturing systems may include one or more process chambers. During processing, a substrate (e.g., a wafer) may rest on a substrate support in a process chamber and the substrate may be heated. Conventionally, heating is provided by resistive heaters within the substrate support.

### SUMMARY

In one aspect of the invention, a substrate support assembly includes a ceramic plate and a cooling base coupled to the ceramic plate. A light absorbing object is disposed in the ceramic plate and a light transmission media is disposed in the cooling base. The light transmission media is to direct light onto the light absorbing object to heat the light absorbing object.

In another aspect of the invention, a substrate support assembly includes a ceramic plate and a cooling base coupled to the ceramic plate. The ceramic plate comprises a top surface and a bottom surface, wherein the top surface is to support a substrate. The base comprises a recess at a location of the light absorbing object. The base additionally includes a light carrying medium disposed in the base, the light carrying medium to direct light onto the light absorbing object to heat the light absorbing object, wherein the light absorbing object is to heat a region of the ceramic plate.

In another aspect of the invention, a method of managing a temperature of a substrate includes heating a ceramic plate of a substrate support assembly using a plurality of resistive heating elements. The method further includes optically heating a plurality of light absorbing objects disposed in or on the ceramic plate. A light absorbing object of the plurality of light absorbing objects is optically heated by passing light through a light transmission media that is disposed inside of a cooling base coupled to the ceramic plate, wherein the light is emitted by the light transmission media onto the light absorbing object to optically heat the light absorbing object, and wherein the optically heated light absorbing object heats a region of the ceramic plate.

Numerous other aspects of the invention are described herein. Other features and aspects of embodiments of the present invention will become more fully apparent from the following description, the appended claims, and the accompanying drawings.

### BRIEF DESCRIPTION OF THE DRAWINGS

Implementations of the present invention are illustrated by way of example, and not by way of limitation, in the figures of the accompanying drawings in which like references indicate similar elements.

FIG. 1 illustrates a schematic top view of an electronic device processing system including a system for performing optical heating in one or more process chambers according to implementations described herein.

FIG. 2 illustrates a schematic partially cross-sectioned view of a substrate temperature control system for optical heating of light absorbing objects in a ceramic plate, according to implementations described herein.

FIG. 3 illustrates a schematic top view of a portion of a substrate support assembly showing optical fibers disposed in the substrate support assembly according to implementations described herein.

FIG. 4 illustrates a cross-sectional side view of a portion of a substrate support assembly with light-based heating using remote light sources, in accordance with implementations of the present invention.

FIG. 5 illustrates a cross-sectional side view of a portion of another substrate support assembly with light-based heating capability using local light sources, in accordance with implementations of the present invention.

FIG. 6 illustrates a cross-sectional side view of a portion of a substrate support assembly with light-based heating capability using remote light sources, in accordance with implementations of the present invention.

FIGS. 7A-C illustrate example configurations of light absorbing objects, in accordance with implementations of the present invention.

FIG. 8 illustrates a flowchart depicting a method of managing a temperature of a substrate during a manufacturing process, in accordance with implementations of the present invention.

FIG. 9A illustrates one example of a heat profile of an optically heated ceramic plate.

FIG. 9B illustrates one example of a heat profile of a ceramic plate that includes optically heated light absorbing objects.

### DETAILED DESCRIPTION OF EMBODIMENTS

Aspects of the present invention provide a substrate support assembly that includes optical fibers or other light transmission media that are used to optically heat light absorbing objects disposed in or on a ceramic plate of the substrate support assembly. substrates supported by the substrate support assembly. The substrate support assembly may include a ceramic plate coupled to a base. The ceramic plate has a top surface that is to support a substrate and a bottom surface that may be bonded to the base. The ceramic plate includes the light absorbing objects embedded in the ceramic plate or bonded to the bottom surface of the ceramic plate. The base includes multiple channels and light transmission media such as light pipes or optical fibers disposed in the channels. The light transmission media may be oriented in the base so as to direct light onto the light absorbing objects. The light absorbing objects may then heat up in response to illumination by the light, and may act as point sources of heat in the ceramic plate. The optically heated light absorbing objects may be used in conjunction with resistive heating elements to uniformly heat a substrate supported by the ceramic plate. By optically heating the light absorbing objects rather than the ceramic plate itself, the temperature profile of the ceramic plate and of a substrate supported by the ceramic plate may be more accurately controlled.

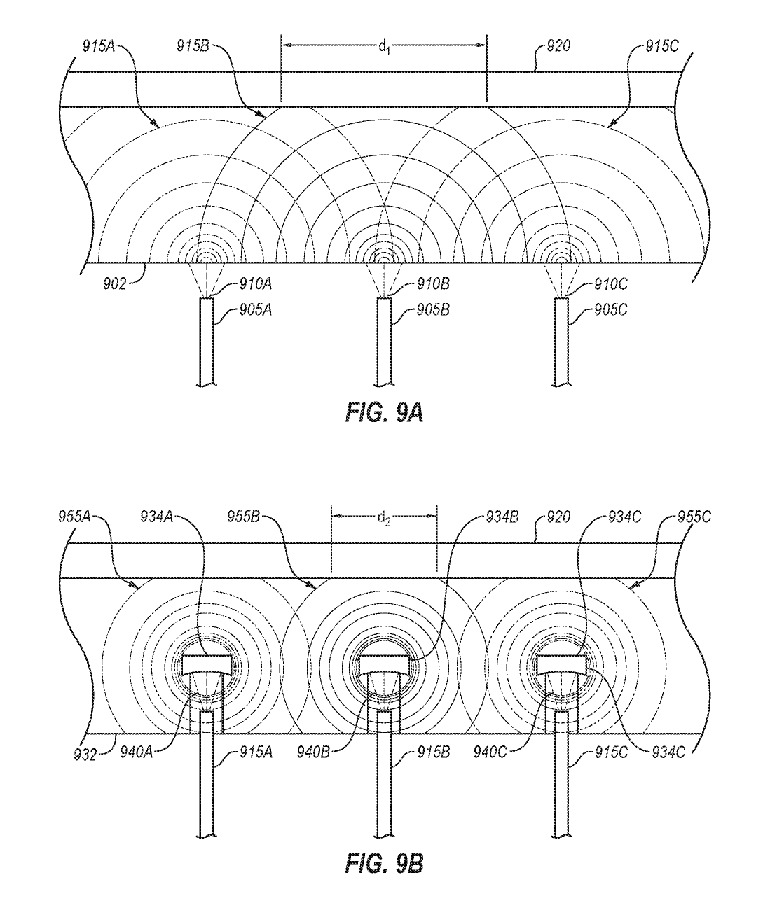

FIG. 9A illustrates an example heat profile of a ceramic plate 902 that is optically heated by light 910A, 910B, 910C from three optical fibers 905A, 905B, 905C. As shown, heat 915A, 915B, 915C radiates out from each of the locations of the ceramic plate 902 that are illuminated by the optical fibers 905A-C. At the top of the ceramic plate 902 where it interfaces with a supported substrate 920, the area d₁ of the substrate 920 that is affected by the heat from a particular optical fiber can be relatively large. Accordingly, pinpoint heating of the substrate 920 can be challenging.

FIG. 9B illustrates an example heat profile of a ceramic plate 932 that includes multiple light absorbing objects 934A, 934B, 934C that are optically heated by light 940A, 940B, 940C from three optical fibers 945A, 945B, 945C. The light absorbing objects 934A-C are designed to maximize an amount of energy that is absorbed from the light 940A-C, and so use of the light absorbing objects improves an efficiency of optical heating. Additionally, the light absorbing objects 934A-C are disposed within the ceramic plate away from the bottom of the ceramic plate. As shown, heat 955A, 955B, 955C radiates out from each of the light absorbing objects 934A-C that are illuminated by the optical fibers 945A-C. Accordingly, at the top of the ceramic plate 932 where it interfaces with a supported substrate 950, the area d₂ of the substrate 950 that is affected by the heat from a particular optical fiber can be much smaller than the area d₁ from FIG. 9A. The smaller affected area of the substrate 950 enables pinpoint heating of regions of the substrate 950.

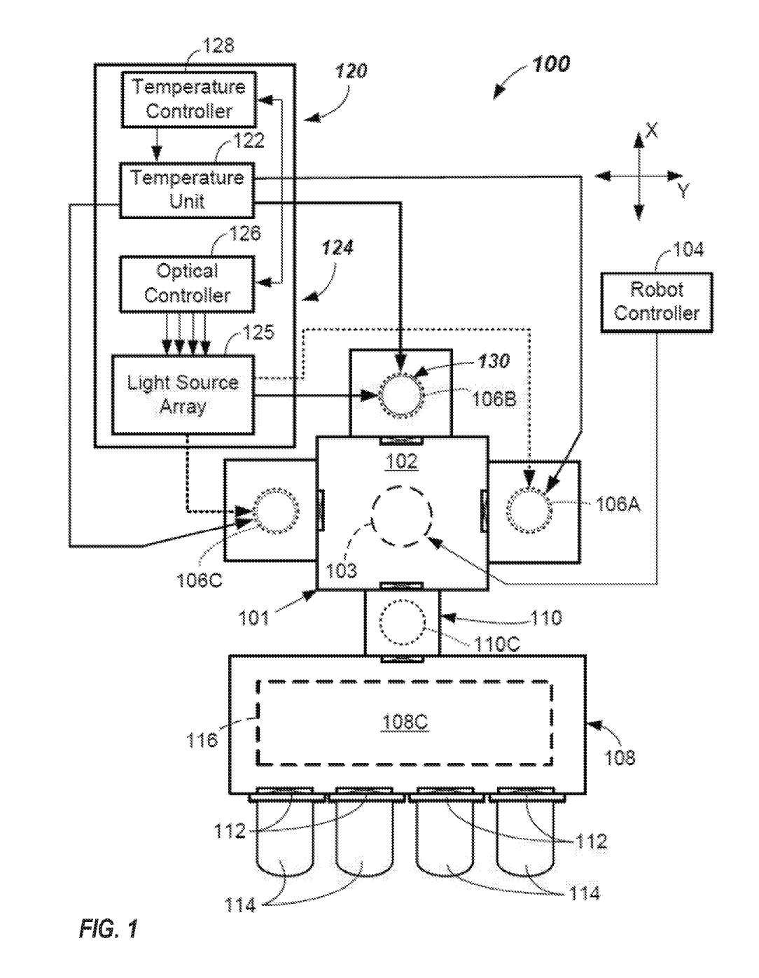

FIG. 1 illustrates a schematic top view diagram of an example embodiment of an electronic device processing system 100 including an optical heating system according to one or more implementations of the present invention. The electronic device processing system 100 may include a housing 101 having walls defining a transfer chamber 102. Walls may include side walls, floor, and ceiling, for example. A robot 103 (shown as a dotted circle) may be at least partially housed within the transfer chamber 102. The robot 103 may place or extract substrates to and from various destinations via operation of moveable arms of the robot 103. “Substrates” as used herein shall mean articles used to make electronic devices or electrical circuit components, such as silicon-containing wafers or articles, patterned or masked silicon wafers or articles, or the like. However, the apparatus, systems, and methods described herein may have broad utility wherever temperature control of a substrate is useful. Implementations of the invention may be useful for rapid heating and cooling of substrates.

The motion of the various arms of the robot 103 may be controlled by suitable commands to a drive assembly (not shown) containing a plurality of drive motors from a robot controller 104. Signals from the robot controller 104 may cause motion of the various components of the robot 103 to cause movement of substrates between the process chambers 106A-106C and one or more load lock chambers 110C.

In the depicted implementation, transfer chamber 102 may have one or more process chambers 106A-106C coupled to and accessible therefrom, at least some of which are adapted to carry out processing at elevated temperatures on the substrates inserted therein. The process chambers 106A-106C may be coupled to facets of the housing 101, and each process chamber 106A-106C may carry out a suitable process (e.g. a PECVD process or etch process) on the substrates. It should be understood that the substrate support assembly 130 described herein may have utility for other processes taking place at elevated temperature, such as physical vapor deposition, etch and ion implant, or the like. In particular, one or more of the processes taking place in the process chambers 106A-106C may include temperature control via direct optical heating of a substrate in accordance with aspects of the invention.

Within the electronic device processing system 100, substrates may be received from a factory interface 108, and also exit the transfer chamber 102 into the factory interface 108 through load lock chamber 110C of a load lock apparatus 110. The factory interface 108 may be any enclosure having wall surfaces forming the factory interface chamber 108C. One or more load ports 112 may be provided on some surfaces of the factory interface 108 and may be configured and adapted to receive (e.g., dock) one or more substrate carriers 114 (e.g., front opening unified pods—FOUPs) such as at a front surface thereof.

Factory interface 108 may include a suitable load/unload robot 116 (shown dotted) of conventional construction within a factory interface chamber 108C. The load/unload robot 116 may be configured and operational to extract substrates from the interior of the one or more substrate carriers 114 and feed the substrates into the one or more load lock chambers 110C of load lock apparatus 110.

In accordance with one or more implementations of the invention, a substrate support assembly 130 that includes a substrate support (e.g., an electrostatic chuck) may be provided in one or more of the process chambers 106A-106C. The substrate support may be a ceramic plate, which may be coupled to a cooling base. The ceramic plate includes one or more light absorbing objects disposed in or bonded to the ceramic plate. The cooling base may be a metal cooling base or other thermally conductive cooling base (e.g., a cooling base formed from an AlSiSiC composite). The cooling base includes channels into which light transmission media such as optical fibers or optically transparent rods are inserted. The light transmission media are oriented to direct light onto the light absorbing objects in or on the ceramic plate. As will be apparent from the following, a substrate support assembly 130 adapted to provide light-based heating of a substrate is provided. The description herein will focus on providing the substrate support assembly 130 in process chamber 106B. However, an identical or similar substrate support assembly 130 may be included in one or both of the other process chambers 106A, 106C. The substrate support assembly 130 may also be used in any other types of process chambers. In some embodiments, the substrate support assembly 130 may be included in all process chambers 106A-106C. More or less numbers of process chambers including the substrate support assembly 130 may be provided.

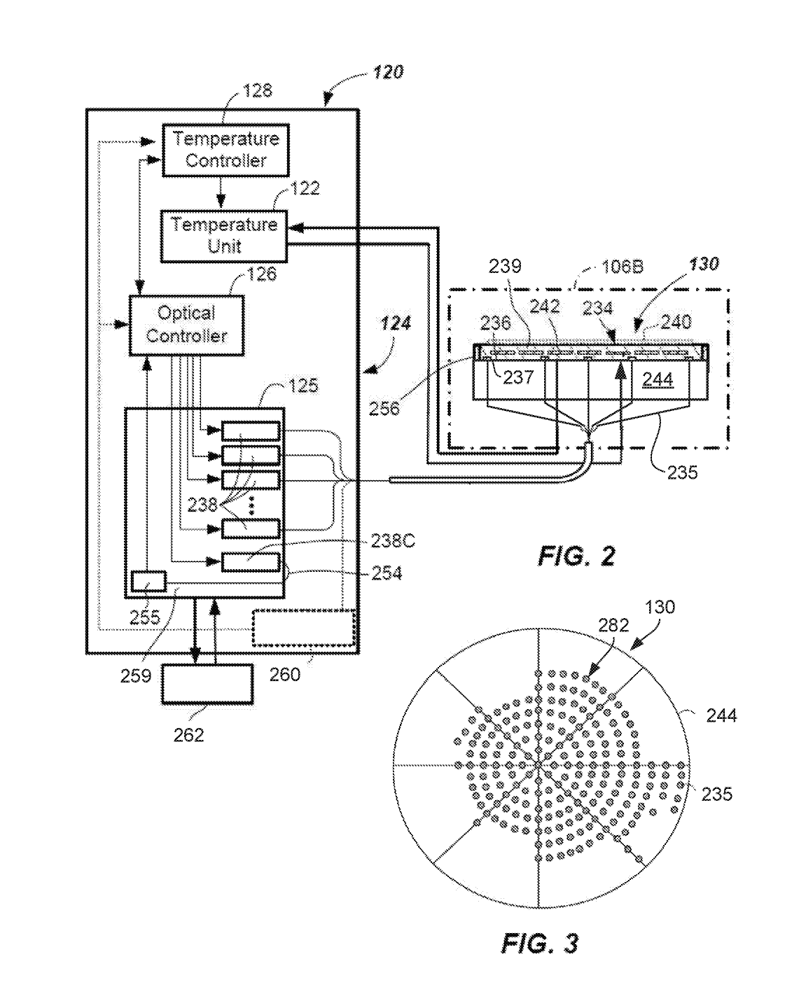

FIG. 2 illustrates a schematic partially cross-sectioned view of a substrate temperature control system 120 that performs optical heating. In the illustrated example, light sources 238 are remote from a substrate support assembly 130 and are external to process chamber 106B. The light sources may be coupled to optical fibers 235. The optical fibers 235 may be inserted into channels in the cooling base 244 and/or ceramic plate 234 of substrate support assembly 130. Light from the light sources 238 may be directed through the optical fibers 235 and directed onto light absorbing objects 237 disposed in or on the ceramic plate 234.

Referring now to FIGS. 1 and 2, in some implementations, a temperature unit 122 may be coupled to one or more resistive heating elements 242. The resistive heating elements 242 may be used in conjunction with optical heating provided by the substrate support assembly 130 to control a temperature of one or more portions of a substrate 240 to achieve a target temperature. The resistive heating elements 242 may provide a first level of temperature control of a substrate support (e.g., of a ceramic plate or electrostatic chuck) and/or supported substrate 240 and the optical fibers 235 and light absorbing objects 237 may provide a second level of temperature control of the substrate 240. The cooling base 244 may provide a third level of temperature control of the substrate 240.

In some implementations, the substrate support assembly 130 may not include resistive heating elements 242. Instead, optical fibers 235 and light absorbing objects 237 may provide a level of temperature control of the substrate 240 via optical heating.

The optical fibers 235 may be made of sapphire, plastic, quartz, glass, and/or other materials. Optical fibers 235 may include any suitable optical fiber type, such as graded-index optical fiber, step-index single mode optical fiber, multi-mode optical fiber, or even photonic crystal optical fiber. Optical fibers 235 that exhibit relatively high bend resistance may be used in some embodiments. Relatively high numerical aperture (NA) fibers may be used, such as NA of greater than about 0.1, greater than about 0.2, or even greater than about 0.3. Any suitable number of optical fibers 235 may be used, such as 20 or more, 50 or more, 100 or more, 200 or more 300 or more, 400 or more, and even up to 500 or more. Some of the optical fibers 235 may be fiber thermocouples. The optical fibers 235 may have coatings to improve performance in some embodiments.

At a system level, temperature control may be provided by a substrate temperature control system 120. Substrate temperature control system 120 may be a subpart of the electronic device processing system 100. Substrate temperature control system 120 may include the temperature unit 122 that may couple and provide power to the resistive heating elements 242 (e.g., metal resistive heating elements or traces) and which may constitute a first source of temperature control (e.g., heating) to one or more of the chambers (e.g., process chambers 106A, 106B, 106C).

An optical heating system 124 may operate as a second heating system in conjunction with the temperature unit 122 and resistive heating elements 242 in some embodiments. Alternatively, substrate temperature control system 120 may not include temperature unit 122, and optical heating system 124 may be used to control the temperature of substrates. For example, the optical heating system 124 may be the only heating system adapted to heat the substrates 240 within the one or more process chambers 106A-106C.

Optical heating system 124 may include a light source array 125 or a single light source coupled (e.g., optically coupled) to the substrate support assembly 130, and an optical controller 126. The light source array 125 may include multiple light sources 238. Each light source 238 may be a laser diode, such as a single emitter diode, in some embodiments. Alternatively, each light source 238 may be a halogen lamp. The laser diode may have any suitable output wavelength range, such as between about 915 nm and about 980 nm, for example. Other wavelengths may also be used. Output power of the light sources 238 may be modulated between about 0 W to about 10 W in some examples. However, ever higher power light sources 238 (e.g., >10 W) may be used. Between about 1 and about 500 light sources 238 may be used in some implementations. As shown, the light sources 238 may be rest upon or be in thermal engagement with a common heat sink 259, which may be cooled (e.g., liquid cooled) to between about 20° C. and about 30° C. by a cooling source 262. Cooling source 262 may be a source of chilled water, for example. Other types of cooling sources 262 may be used. In implementations where the light sources 238 are included in the substrate support assembly 130, the common heat sink 259 may be integrated into the substrate support assembly as a cooling base.

Each light source 238 may be individually controlled and modulated from a low or zero level of optical power output to a high or maximum level of optical power output. Each light source 238 may be individually controlled in order to control temperature at finite points (pixels) or collectively controlled in groups of optical fibers and/or light pipes to control temperatures of one or more regions or zones of the substrate 240.

Any suitable temperature control philosophy may be implemented. In one control aspect, a highly uniform temperature distribution across an upper surface of the substrate 240 may be sought. In another aspect, a deliberately non-uniform temperature distribution may be implemented (e.g., hotter or cooler at an edge of the substrate 240). Each temperature profile may be provided in accordance with aspects of the invention depending on the control philosophy implemented by the optical controller 126.

Substrate temperature control system 120 may include a temperature controller 128 operational to control temperature of the substrate 240 that is being temperature controlled within the chamber (e.g., process chamber 106B). Temperature controller 128 may be operational to control the temperature unit 122 and may interface with the optical controller 126 in some embodiments. The temperature controller 128 may be used to communicate with the optical controller 126 and/or the temperature unit 122 to control a temperature of the substrate 240 supported by the substrate support assembly 130.

FIG. 3 illustrates a schematic top view of a portion of a substrate support assembly 130 with the ceramic plate removed to show positioning of the optical fibers 235 according to some implementations. As shown, cooling base 244 includes multiple through channels 282, and optical fibers 235 are inserted into those channels 282.

FIG. 3 shows one possible pattern of a plurality of optical fibers 235. Any suitable arrangement may be made for inclusion of the plurality of optical fibers 235. In one such example, there may be between 10 to 500 channels 282 in the cooling base 244 that include optical fibers 235. Although a very specific pattern is depicted in FIG. 3 for illustrative purposes, other different patterns (e.g., a symmetric pattern) may also be used. It is to be understood that FIG. 3 illustrates only one of many layout possibilities.

Now referring to FIGS. 2 and 3, the substrate support assembly 130, which is included in optical heating system 124, is described in more detail. Optical heating system 124 may include substrate support assembly 130. The substrate support assembly 130 includes ceramic plate 234. The ceramic plate 234 may be an electrostatic chuck that supports substrate 240, and may include an embedded chucking electrode. Substrate support assembly 130, as shown, includes ceramic plate 234 with embedded resistive heating elements. In some implementations, the ceramic plate 234 is an electrostatic chuck. In other implementations, the ceramic plate 234 is a vacuum chuck. The substrate support assembly 130 additionally includes a cooling base 244 coupled to a bottom surface 236 of the ceramic plate 234. In one implementation, sidewalls of the ceramic plate 234 and/or cooling base 244 are coated by a plasma resistant coating 256 such as yttria (Y₂O₃), yttrium aluminum garnet (YAG, Y₃Al₅O₁₂), or a ceramic compound comprising Y₄Al₂O₉ and a solid-solution of Y₂O₃—ZrO₂. A top surface of the ceramic plate 234 (including ends of rods or optical fibers 235) may also be coated by the plasma resistant coating 256.

The cooling base 244 may be formed of a metal or other thermally conductive material such as aluminum, stainless steel, an AlSiSiC composite, and so on. The cooling base 244 may include channels (not shown) that are filled with a cooling liquid. The ceramic plate 234 may be AlN or Al₂O₃ in some implementations.

The cooling base 244 may include multiple channels 282 into which optical fibers 235, optically transparent rods, or other light transmission media are inserted. The optical fibers 235, rods or other light transmission media may be oriented perpendicular to a bottom surface of the ceramic plate 234 as shown. Some or all of the optical fibers 235, rods or other light transmission media may also have other orientations in the base 244, such as at angles of between 45-90 degrees in relation to the bottom surface of the ceramic plate 234.

A top surface 239 of the ceramic plate 234 may have surface features such as mesas, rings, grooves, and so forth. The ceramic plate 234 may include gas channels for delivering backside gas such as helium to a region between the substrate 240 and the top surface 239. The ceramic plate 234 may also include gas channels for pumping air out of the region between the substrate 240 and the top surface 239 to form a vacuum in the region. Use of helium in the region may improve thermal contact between the substrate 240 and the ceramic plate 234. Use of a vacuum in the region may decrease the thermal contact (and improve thermal separation) between the ceramic plate 234 and the substrate 240.

The plurality of optical fibers 235 are adapted to provide light-based heating of the substrate 240. The plurality of optical fibers 235 may terminate at multiple locations in the cooling base 244 and/or ceramic plate 234. One example layout of the optical fibers 235 in the cooling plate 244 is shown in FIG. 3. Optical heating system 124 may include the light source array 125 including a plurality of light sources 238 coupled to at least some, and preferably most or all, of the plurality of optical fibers 235 and/or optical guide. The optical controller 126 may be configured to control light power (e.g., intensity) channeled into, and carried by, the plurality of optical fibers 235 and/or optical guide.

In operation, light carried in at least some of the plurality of optical fibers 235 is used to heat the light absorbing objects 237. Heat radiates from the light absorbing objects 237 to heat portions of the ceramic plate 234 as well as portions of the substrate 240. When the plurality of optical fibers 235 are positioned and terminated at different locations, many local portions of the substrate 240 (or all of the substrate) may be heated. In some implementations, this heating may be in conjunction with temperature control provided by the temperature unit 122 and the resistive heating elements 242. In other implementations, the heating by the plurality of optical fibers 235 and/or optical guide may be the only heating provided to the substrate 240.

For example, temperature control may, in some implementations, cause the substrate 240 (shown dotted) to be heated to a nominal temperature of greater than about 120° C., greater than 200° C., greater than about 500° C., greater than about 600° C., or even about 650° C. or a greater temperature. Such heating may be carried out on substrates 240 within the one or more process chambers 106A-106C in some implementations. For example, temperature control may, in some implementations, cause the substrate 240 (shown dotted) to be heated, such as in a PECVD process, an etch process, an atomic layer deposition (ALD) process, and so on.

One or more channels may be drilled into the cooling base 244 and/or ceramic plate 234 to provide access for electrical lines to connect to the resistive heating elements 242 (also referred to as heating elements) and/or to one or more electrodes. The electrodes may include a chucking electrode that is used to secure a substrate to the substrate support assembly and/or a radio frequency (RF) electrode. The chucking electrode may use electrostatic forces to pull the substrate towards the ceramic plate.

In addition to optical fibers 235 that are used to provide heating, some optical fibers 235 may be used as fiber optic temperature sensors to measure a temperature of the substrate and/or a temperature of the ceramic plate. For example, some optical fibers 235 may be fiber optical thermocouples. Additionally or alternatively, temperature of the substrate and/or temperature of the ceramic plate may be measured by the optical fibers using infrared pyrometry. The fiber optical thermocouples and/or other fiber optical temperature sensors may be used to measure the temperature of the ceramic plate and/or substrate at various regions. Each optical fiber that is a component of a fiber optic temperature sensor may be used to measure a temperature at a region of the ceramic plate and/or substrate. Optical fibers that are to measure a temperature of the substrate in some embodiments are routed through a channel or gas passage in the ceramic plate and directed at the substrate. In some embodiments, optical fibers may be used both for heating and for temperature measurement. For example, an optical fiber may be split into two portions at one end. A first portion may be routed to an optical heat source such as a laser diode and a second portion may be routed to a temperature sensor.

In some implementations, one or more of the light sources 238C may be coupled by a sensor fiber 254 to a control sensor 255, such as a light receiver (e.g., photodiode). A control sensor 255 may be used to provide feedback to the optical controller 126 on a relative output of a control light source 238C (e.g., of light intensity or heat generation, for example). Optionally or in addition, one or more optical temperature sensors may be provided in one or more channels in the cooling base 244 and/or ceramic plate 234 and coupled to a temperature measuring system 260 to enable localized temperature monitoring of an inside portion of the substrate support assembly 130. For example, the optical temperature sensor may be a fiber Bragg grating coupled to a spectrometer, which may be the temperature measuring system 260. A fiber multiplexer or other like component may be used to connect multiple optical temperature sensors to a single spectrometer. An optical temperature sensor may also be accomplished by other suitable means, such as by embedding a tip of an optical fiber in a suitable adhesive material (e.g., CERAMACAST 865 available from Aremco Products Inc. of Valley Cottage, N.Y.) and measuring the thermal radiation emitted by that material. Thermal measurement may be accomplished by coupling the optical fiber to an indium gallium arsenide photodiode. The optical fibers or optically transparent rods coupled to the optical temperature sensor may also be placed in a channel in the cooling base 244 and/or ceramic plate 234. Any suitable temperature measuring system 260 may be used to interrogate the optical temperature sensor. Temperature measuring system 260 may interface with the temperature controller 128 and/or the optical controller 126 to provide temperature feedback. Optionally or additionally, thermal feedback by other methods, such as two or more RTDs on the substrate support assembly 130 may be used.

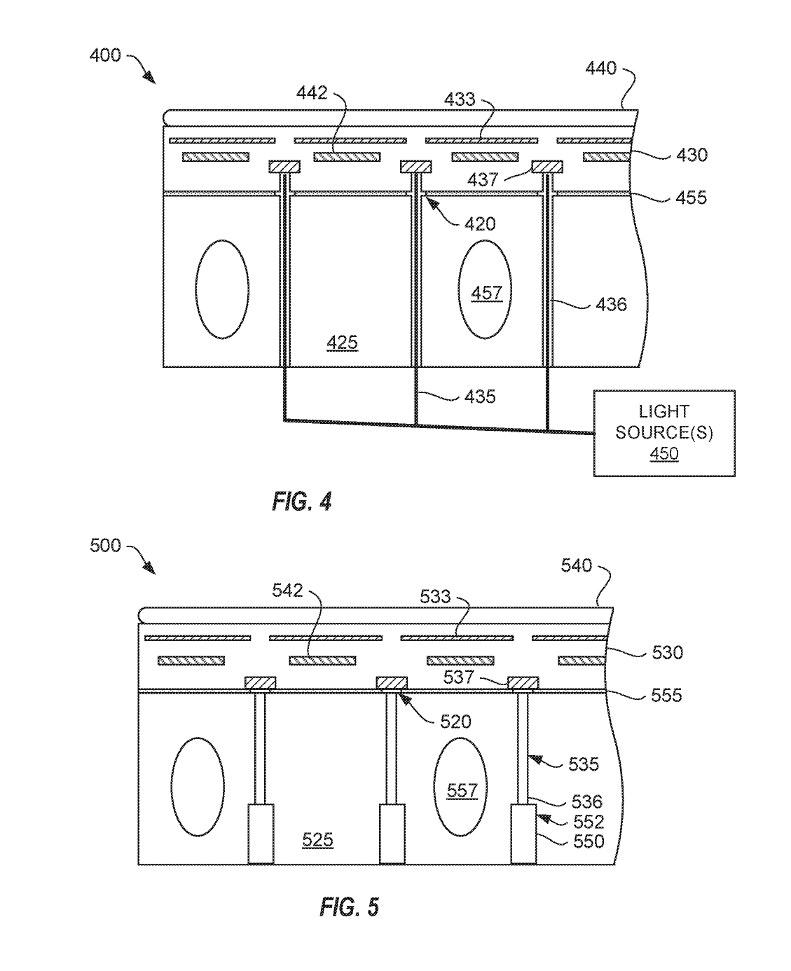

FIG. 4 illustrates a cross-sectional side view of a portion of a substrate support assembly 400 with light-based heating capability, in accordance with implementations of the present invention. The substrate support assembly 400 includes a ceramic plate 430 coupled to a cooling base 425.

The ceramic plate 430 may be aluminum nitride (AlN) or aluminum oxide (Al₂O₃) in implementations. The ceramic plate 430 includes a top surface that supports a substrate 440 and a bottom surface that interfaces with the cooling base 425. The ceramic plate 430 in one implementation includes resistive heating elements 442 and an electrode layer 433. The resistive heating elements 442 may heat the ceramic plate to a target temperature. Alternatively, the ceramic plate 430 may not include any resistive heating elements 442.

The electrode layer 433 may be a radio frequency (RF) electrode that may be used for directing plasma. For example, an RF signal may be applied to the electrode layer 433 during processing of a supported substrate. The electrode layer 433 may alternatively or additionally be a chucking electrode that is used to electrostatically chuck or secure the substrate 440. The electrode layer 433 may be molybdenum, aluminum, tungsten, or another material with high electrical conductivity. In some embodiments, the electrode layer 433 is a fine mesh of metal lines having a thickness and/or width of about 25-125 microns. The electrode layer 433 may be referred to as an electrode mesh. Accordingly, in embodiments the ceramic plate 430 is an electrostatic chuck. The ceramic plate 430 may be used for Johnsen-Rahbek and/or Coulombic electrostatic chucking in embodiments.

The ceramic plate 430 includes multiple light absorbing objects 437 disposed within the ceramic plate 430. The light absorbing objects may be metal objects such as molybdenum (Mo), tungsten (W), stainless steel, titanium (Ti), a nickel-cobalt ferrous alloy (e.g., Kovar®), and so on. The light absorbing objects may be screen printed objects, premanufactured objects, or a metal mesh. In one implementation the ceramic plate 430 is AlN, and the light absorbing object 437 is a molybdenum tablet (or other molybdenum object). Molybdenum has a coefficient of thermal expansion that is very close to the coefficient of thermal expansion of AlN. Accordingly, the molybdenum light absorbing object may not cause the ceramic plate 430 to crack due to a mismatch in the coefficient of thermal expansion (CTE) during heating and cooling. The light absorbing objects may also be a metal-ceramic composite. The metal-ceramic composite may be composed of mixtures of AlN and W, mixtures of or AlN and TiN, mixtures of AlN and Mo, and so on. The metal-ceramic composite may provide improved bonding to the ceramic plate over pure metal light absorbing objects. Additionally, the metal-ceramic composite may have a CTE that closely matches the CTE of the ceramic plate 430.

The light absorbing objects 437 may be tablet shaped, rectangular, square disc-shaped, and/or have other shapes. The light absorbing objects 437 may have a thickness of anywhere from about 50 microns to about 4 mm. In some implementations, such as where a metallization process is used to form the light absorbing objects 437, the light absorbing objects 437 have a thickness of about 50-200 microns. In other implementations, such as when preformed metal light absorbing objects are used, the light absorbing objects 437 may have a thickness of about 1-4 mm (e.g., 1 mm, 2 mm, 3 mm, or 4 mm). The light absorbing objects 437 may have a width and length (or a diameter) that is larger than the diameter of the beam of light from the optical fiber 435 that will heat the light absorbing object 437. For example, the light absorbing objects may have a diameter of about 2-5 mm in some implementations.

The light absorbing objects 437 may be formed within the ceramic plate 430 using the same process that is used to form the electrode layer 433 and/or resistive heating elements 442. For example, the light absorbing objects may be formed on or bonded to a first surface of a thin ceramic plate. In one example, the light absorbing objects are screen printed onto the thin ceramic plate by printing a metal-ceramic composite paste onto the thin ceramic plate. The metal-ceramic composite paste may include a metal (e.g., W or Mo), a ceramic (e.g., AlN or Al₂O₃) and a binder. The binder may be polyvinyl alcohol (PVA) or another organic binder. The metal-ceramic composite paste may be heated (e.g., to a temperature of about 500-800° C.) to burn off the organic binder and leave behind the metal-ceramic composite. The first surface of the thin ceramic plate may then be diffusion bonded to another thin ceramic plate to form a single monolithic ceramic plate that includes the light absorbing objects embedded inside. Bores may then be drilled in the bottom surface of the ceramic plate 430 to expose the light absorbing objects.

In another implementation, the light absorbing objects 437 may be formed by machining recesses or holes in the bottom surface of the ceramic plate 430. The light absorbing objects may then be inserted into the recesses or holes and bonded to the recesses or holes. The bonding may be performed, for example, by brazing.

In another implementation, the light absorbing objects may be formed by machining recesses or holes in the bottom surface of the ceramic plate 430. A metal-based paste may then be added to the recesses or holes. The metal-based paste can be made up of one or more of silver (Ag), copper (Cu), gold (Au), nickel (Ni), titanium (Ti), and/or aluminum (Al). For example, the metal-based paste may be a silver copper alloy, a titanium, silver copper alloy, or another alloy. The metal-based paste may also be any of the metal-ceramic composite pastes described above. Enough paste may be inserted into the recesses or holes to partially fill or entirely fill the recesses or holes. Heat may then be applied to metallize the paste and form the light absorbing objects. In some implementations, a metal foil may be used rather than a metal-based paste. The metal foil may be cut to a size appropriate to partially or entirely fill the recesses or holes, and may then be heated to melt and reflow the metal foil to form the light absorbing objects.

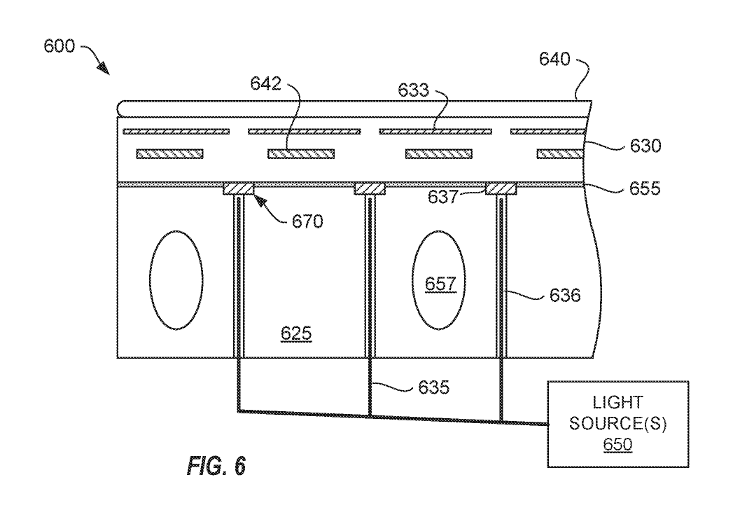

In another implementation, the light absorbing objects 437 may be bonded to the bottom surface of the ceramic plate 430, as shown in FIG. 6.

Light absorbing objects 437 maybe configured to maximize light absorption. In some implementations, a surface of the light absorbing objects that will be exposed to light has a concave shape. For example, the surface may have a half-pipe shape (e.g., an inverted U-shape), a parabolic dish shape, an inverted spherical shape, or other concave shape. The surface of the light absorbing objects 437 may additionally or alternatively include slits, grooves, divots, and so on to increase light absorption. Additionally, or alternatively, the surface of the light absorbing object may be coated with a light absorbing coating that increases light absorption (e.g., a black coating). Additionally, or alternatively, the surface of the light absorbing object may be roughened to increase the roughness of the surface and increase light absorption. In some implementations, the light absorbing objects have a light absorption of about 90-98%, and may function nearly as a black body.

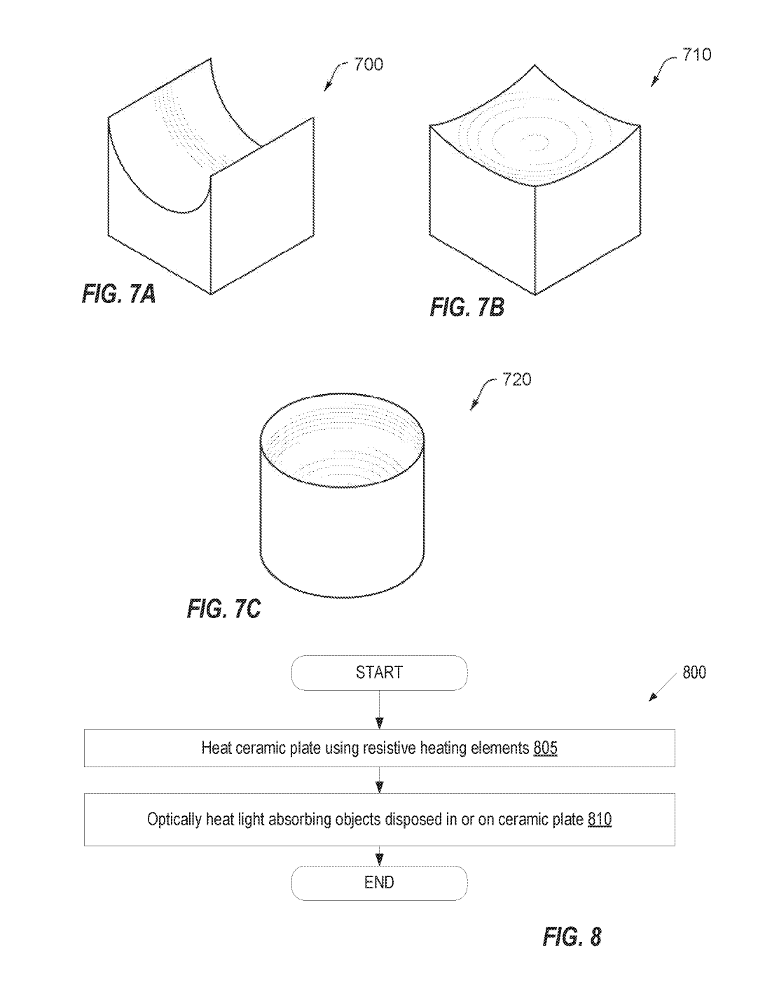

FIGS. 7A-C illustrate some example designs for light absorbing objects. FIG. 7A illustrates a square light absorbing object 700 with a surface having a half-pipe shape. FIG. 7B illustrates a square light absorbing object 710 with a surface having a parabolic dish shape. FIG. 7C illustrates a tablet-shaped light absorbing object 720 with a surface having an inverted spherical shape (e.g., a bowl shape).

Referring back to FIG. 4, the cooling base 425 is a metal plate that is responsible for cooling the ceramic plate 430 and optionally a supported substrate 440. The cooling base 425 includes multiple channels 457 that receive a coolant. The cooling base 425 may be, for example, aluminum or stainless steel. Other metals other thermally conductive materials such as AlSiSiC composite may also be used for the cooling base 425. In some embodiments, an RF signal is applied to the cooling base 425 during processing of a supported substrate.

The cooling base 425 may be coupled to the ceramic plate 430 by a bond layer 455. The bond layer 455 may be a silicone bond, a metal bond, a glue, a braze, or another type of bond. The bond layer 455 may be a perforated bond layer that includes holes 420 or gaps in the bond layer at regions proximate to the channels 436. The bond layer 455 may not be transparent to light at the wavelengths of light emitted by the light sources 450. Accordingly, the bond layer may have holes 420 to permit passage of light past the bond layer 455 without absorption by the bond layer 455. The cooling base 425 may also be secured to the ceramic plate 430 by other coupling means in addition to or instead of bond layer 455. Examples of other coupling means include fasteners, springs that press the cooling base 425 against the ceramic plate 430, and so on.

The cooling base 425 includes multiple channels 436 to receive light carrying media such as optical fibers 435. Channels in the cooling base 425 may align with channels in the ceramic plate 430. The light carrying media are inserted into the channels 436, and so are disposed inside of the cooling base 425 and possibly inside of the ceramic plate 430.

Optical fibers 435 may be coupled at one end to one or more light sources 450. The coupling may be a physical coupling or an optical coupling that may not include a physical connection. Accordingly, light from an optical fiber 435 will be directed onto a light absorbing object 437.

The light sources 450 may be inside of a processing chamber that houses the substrate support assembly 400 or may be external to the processing chamber. The light sources may be, for example, laser diodes, light emitting diodes (LEDs), fiber lasers, halogen lamps, or conventional lights with a lens system. The light sources 450 may provide continuous or pulsed light. In an implementation, approximately 1000 watts (e.g., in the range of 200 W to 2000 W) is used for heating through the optical fibers 435. Implementations are able to achieve temperature uniformity over a substrate (e.g., over a 300 mm wafer) that has a temperature variance of less than 1 degree.

FIG. 5 illustrates a cross-sectional side view of a portion of a substrate support assembly 500 with light-based heating capability, in accordance with implementations of the present invention. The substrate support assembly 500 includes a ceramic plate 530 coupled to a cooling base 525. The ceramic plate 530 and/or cooing base 525 may be substantially similar to the ceramic plate 430 and/or cooling base 425, respectively, in some implementations.

The ceramic plate 530 may be composed of any of the materials discussed with reference to ceramic plate 430. The ceramic plate 530 includes a top surface that supports a substrate 540 and a bottom surface that interfaces with the cooling base 525. The ceramic plate 530 in one implementation includes resistive heating elements 542 and an electrode layer 533. The resistive heating elements 542 may heat the ceramic plate to a target temperature. Alternatively, the ceramic plate 530 may not include any resistive heating elements 542. The electrode layer 533 may be a radio frequency (RF) electrode that may be used for directing plasma. The electrode layer 533 may alternatively or additionally be a chucking electrode that is used to electrostatically chuck or secure the substrate 540. Accordingly, in embodiments the ceramic plate 530 is an electrostatic chuck. The ceramic plate 530 may be used for Johnsen-Rahbek and/or Coulombic electrostatic chucking in embodiments.

The ceramic plate 530 additionally includes multiple light absorbing objects 537. The light absorbing objects 537 may correspond to any of the light absorbing objects 437 discussed with reference to FIG. 4. In contrast to light absorbing objects 437, light absorbing objects 537 are disposed near a bottom surface of the ceramic plate 530. Accordingly, no bores or holes were drilled to expose the light absorbing objects 537.

The cooling base 525 includes multiple channels 557 that receive a coolant. The cooling base 525 may be, for example, aluminum, an AlSiSiC composite or stainless steel. Other metals or other thermally conductive materials may also be used for the cooling base 525.

The cooling base 525 may be coupled to the ceramic plate 530 by a bond layer 555. The bond layer 555 may be a silicone bond, a metal bond, a glue, a braze, or another type of bond. The bond layer 555 may be a perforated bond layer. The cooling base 525 may also be secured to the ceramic plate 530 by other coupling means in addition to or instead of bond layer 555. Examples of other coupling means include fasteners, springs that press the cooling base 525 against the ceramic plate 530, and so on.

The cooling base 525 includes multiple channels 536 to receive light carrying media such as optically transparent rods 535. The rods 535 may be inserted into the channels 536, and so are disposed inside of the cooling base 525. The cooling base 525 may be a metal cooling base (e.g., aluminum or stainless steel) or other thermally conductive cooling base (e.g., a cooling base formed from an AlSiSiC composite). The cooling base 525 includes multiple channels 557 that are filled with a coolant. The cooling base 525 additionally includes multiple channels 552. Light sources 550 are disposed in the channels 552. Cooling base 525 may act as a heat sink for the light sources 550 and may cool the light sources. Each light source 550 may be aligned with a rod 536. A lens or reflector (not shown) may be disposed in each of the channels 536 and/or 552 near an output of light sources 550 and/or rods 535. The lens or reflector may focus light emitted by the light sources 550.

As shown, light sources 550 are near a bottom of cooling base 525. In other implementations, the light sources 550 may be near a middle of the cooling base or near a top of the cooling base 525. If the light sources 550 are near a top of the cooling base 525, then rods and/or optical fibers may not be used in some implementations.

FIG. 6 illustrates a cross-sectional side view of a portion of a substrate support assembly 600 with light-based heating capability, in accordance with implementations of the present invention. The substrate support assembly 600 includes a ceramic plate 630 coupled to a cooling base 625. The substrate support assembly 600 is substantially similar to substrate support assembly 400 of FIG. 4. For example, the substrate support assembly 600 includes a ceramic plate 630 bonded to a cooling base 625 by a bond layer 655. The ceramic plate 630 supports a substrate 640 and includes resistive heating elements 642 and an electrode layer 633. The cooling base 625 includes channels 657 for receiving a coolant and channels 636 for receiving optical fibers 635. The optical fibers 635 are connected to one or more light sources 650.

A primary difference between substrate support assembly 600 and substrate support assembly 400 is that the ceramic plate 630 of substrate support assembly 600 includes light absorbing objects 637 bonded to a bottom surface of the ceramic plate 630. In contrast, the light absorbing objects 437 of FIG. 4 are embedded inside of the ceramic plate 430. Since the light absorbing objects 637 are bonded to the bottom of the ceramic plate 430, a larger difference in coefficient of thermal expansion between the light absorbing object 637 and the ceramic plate 630 can be tolerated without causing the ceramic plate to crack. The light absorbing object may be any of the light absorbing objects discussed with reference to light absorbing objects 437.

Since the light absorbing objects 637 protrude from the bottom surface of the ceramic plate 630, the top surface of the cooling base 625 is machined to form recesses 670 that will receive the protruding light absorbing objects 637. The recesses 670 enable the cooling base 625 to mate with the ceramic plate 630 without introducing gaps between the cooling base 625 and the ceramic plate 630.

FIG. 8 illustrates a flowchart depicting a method 800 of heating a substrate during a manufacturing process, in accordance with implementations of the present invention. Method 800 may be performed by a substrate support assembly in combination with one or more control systems that may control light emitted by light sources and/or electrodes of the substrate support assembly. The control systems may be coupled to additional systems that may include a recipe for performing a process. The recipe may specify target temperatures, process times, gas flow rates, and so on. Method 800 may be performed as part of a deposition process, an etch process, an implant process, and so on. Method 800 may be performed using any of the substrate support assemblies described herein.

At block 805 of method 800 a substrate supported by the substrate support assembly is heated using resistive heating elements that are embedded in a ceramic plate of the substrate support assembly. The resistive heating elements may provide a first level of temperature control, and may be divided into multiple zones (e.g., 2-4 zones) that are separately heated.

At block 810, the substrate is further heated by optically heating light absorbing objects disposed in or on the ceramic plate. The ceramic plate may include tens or hundreds of light absorbing objects. Each light absorbing objects may be heated by passing photons (e.g., light) through an optical fiber and onto the light absorbing object. The light absorbing objects may each provide pinpoint or pixelated heating to a small region of the substrate. The combination of the resistive heating and the optical heating of the light absorbing objects may enable the substrate to have a highly uniform temperature (e.g., with a temperature variance of about 1 degree C. or less). The high temperature uniformity enables processing of the substrate to be performed with minimal variance over the substrate.

The preceding description sets forth numerous specific details such as examples of specific systems, components, methods, and so forth, in order to provide a good understanding of several implementations of the present invention. It will be apparent to one skilled in the art, however, that at least some implementations of the present invention may be practiced without these specific details. In other instances, well-known components or methods are not described in detail or are presented in simple block diagram format in order to avoid unnecessarily obscuring the present invention. Thus, the specific details set forth are merely exemplary. Particular implementations may vary from these exemplary details and still be contemplated to be within the scope of the present invention.

Reference throughout this specification to “one implementation” or “an implementation” means that a particular feature, structure, or characteristic described in connection with the implementation is included in at least one implementation. Thus, the appearances of the phrase “in one implementation” or “in an implementation,” or the like, in various places throughout this specification are not necessarily all referring to the same implementation. In addition, the term “or” is intended to mean an inclusive “or” rather than an exclusive “or.” When the term “about” or “approximately” is used herein, this is intended to mean that the nominal value presented is precise within ±10%.

It is to be understood that the above description is intended to be illustrative, and not restrictive. Many other implementations will be apparent to those of skill in the art upon reading and understanding the above description. The scope herein should, therefore, be determined with reference to the appended claims, along with the full scope of equivalents to which such claims are entitled.

What is claimed is:

1. A substrate support assembly, comprising:
a ceramic plate, the ceramic plate comprising a top surface and a bottom surface, wherein the top surface is to support a substrate;
a light absorbing object disposed in the ceramic plate;
a base coupled to the bottom surface of the ceramic plate; and
a light carrying medium disposed in the base, the light carrying medium to direct light onto the light absorbing object to heat the light absorbing object, wherein the light absorbing object is to heat a region of the ceramic plate.

2. The substrate support assembly of claim 1, further comprising:
a plurality of light absorbing objects, wherein the light absorbing object is one of the plurality of light absorbing objects, wherein the light carrying medium comprises a plurality of optical fibers, and wherein each optical fiber of the plurality of optical fibers is to direct light onto one of the plurality of light absorbing objects.

3. The substrate support assembly of claim 1, wherein the light absorbing object comprises metal.

4. The substrate support assembly of claim 3, wherein the metal comprises molybdenum or tungsten.

5. The substrate support assembly of claim 1, wherein a surface of the light absorbing object comprises at least one of a plurality of slits or a plurality of divots.

6. The substrate support assembly of claim 1, wherein a surface of the light absorbing object has a concave shape.

7. The substrate support assembly of claim 6, wherein the surface of the light absorbing object has one of a half-pipe shape, a parabolic dish shape or an inverted spherical shape.

8. The substrate support assembly of claim 1, wherein the ceramic plate comprises a bore, and wherein the light absorbing object is disposed inside of the bore.

9. The substrate support assembly of claim 1, wherein the base comprises a cooling base.

10. The substrate support assembly of claim 1, wherein the light absorbing object has a thickness of about 1-3 mm.

11. A substrate support assembly, comprising:
a ceramic plate, the ceramic plate comprising a top surface and a bottom surface, wherein the top surface is to support a substrate;
a light absorbing object bonded to the bottom surface of the ceramic plate;
a base coupled to the bottom surface of the ceramic plate, the base comprising a recess at a location of the light absorbing object; and
a light carrying medium disposed in the base, the light carrying medium to direct light onto the light absorbing object to heat the light absorbing object, wherein the light absorbing object is to heat a region of the ceramic plate.

12. The substrate support assembly of claim 11, further comprising:
a plurality of light absorbing objects bonded to the bottom surface of the ceramic plate, wherein the light absorbing object is one of the plurality of light absorbing objects, wherein the light carrying medium comprises a plurality of optical fibers, and wherein each optical fiber of the plurality of optical fibers is to direct light onto one of the plurality of light absorbing objects.

13. The substrate support assembly of claim 11, wherein the light absorbing object comprises metal.

14. The substrate support assembly of claim 13, wherein the metal comprises at least one of molybdenum, tungsten, titanium, stainless steel or Kovar.

15. The substrate support assembly of claim 11, wherein the light absorbing object has a thickness of about 1-3 mm.

16. The substrate support assembly of claim 11, wherein a surface of the light absorbing object comprises at least one of a plurality of slits or a plurality of divots.

17. The substrate support assembly of claim 11, wherein a surface of the light absorbing object has a concave shape.

18. A method comprising:
optically heating a plurality of light absorbing objects disposed in or on a ceramic plate of a substrate support assembly, wherein a light absorbing object of the plurality of light absorbing objects is optically heated by passing light through a light transmission media that is disposed inside of a cooling base coupled to the ceramic plate, wherein the light is emitted by the light transmission media onto the light absorbing object to optically heat the light absorbing object, and wherein the optically heated light absorbing object heats a region of the ceramic plate.

19. The method of claim 18, wherein optically heating the plurality of light absorbing objects comprises directing first light having a first intensity onto a first light absorbing object of the plurality of light absorbing objects and directing second light having a second intensity onto a second light absorbing object of the plurality of light absorbing objects.

20. The method of claim 18, further comprising:
heating the ceramic plate using a plurality of resistive heating elements.
